(19) United States
(12) Patent Application Publication
(10) Pub. No.: US 2025/0048550 A1
(43) Pub. Date: Feb. 6, 2025

(54) TEXTILE CONDUCTIVE BUS AND METHOD OF MAKING THE SAME

(71) Applicant: The Charles Stark Draper Laboratory, Inc., Cambridge, MA (US)

(72) Inventor: William A. ROY, Cambridge, MA (US)

(73) Assignee: The Charles Stark Draper Laboratory, Inc., Cambridge, MA (US)

(21) Appl. No.: 18/788,652

(22) Filed: Jul. 30, 2024

Related U.S. Application Data
(60) Provisional application No. 63/516,645, filed on Jul. 31, 2023.

(51) Int. Cl. H05K 1/09; H05K 1/11; H05K 3/40

(52) U.S. Cl. CPC H05K 1/09; H05K 1/111; H05K 1/115; H05K 3/4007; H05K 3/4038; H05K 2201/0141

(57) ABSTRACT

A textile conductor and a method of making the same including a textile thread, an electrical bus within the textile thread, wherein the electrical bus includes at least one top electrically conductive pad, at least one bottom electrically conductive pad, and a plurality of rows of a plurality of electrically conductive traces A dielectric material is positioned between the at least one of the at least one top electrically conductive pad, the plurality of rows of the plurality of electrically conductive traces, and the at least one bottom electrically conductive pad. At least one electrically conductive via connects at least one of the at least one top electrically conductive pad and the at least one bottom electrically conductive pad to at least one of the plurality of electrically conductive traces in at least one of the plurality of rows of the plurality of electrically conductive traces.

### CROSS-REFERENCE TO RELATED APPLICATIONS

This application claims priority to U.S. Provisional Patent Application Ser. No. 63/516,645, filed Jul. 31, 2023, the content of which is hereby incorporated by reference in its entirety.

### FIELD OF DISCLOSURE

The present disclosure relates generally to a conductive bus and, in particular, to a conductive bus in textile material.

### BACKGROUND

Conventional approaches to interconnect garment integrated electronics include woven or sewn-in discrete wire (e.g., stranded or solid or single-conductor thread), woven or sewn-in Kapton® flex-circuit cable, surface-deposited conductive inks, and woven-in thread pulling-equipment-produced cable. Discrete wire offers a mature solution but is limited to only one to four conductors in a 1 millimeter (mm) or less diameter wire. Discrete wire also introduces difficult and low-reliability crimp splicing techniques required to connect electronics. Discrete wire also exhibits low flexibility, low tensile strength, and low compatibility with conventional textile equipment.

Kapton® flex-circuit cable is less flexible than discrete wire in most cases. Conductive inks require a large surface area to apply a circuit, will not adhere to many materials, and does not possess an intrinsic insulator sheath. Conductive inks are also inflexible, inconsistent, difficult to test before installation, and exhibit low-reliability over long deployments. Thread pullers are less mature, less flexible, and the inner conductors are difficult to access in a repeatable way due to the nature of the thread-drawing process and lack of via structures capable of delivering the conductor's signal to an outer surface.

### SUMMARY

In accordance with the concepts described herein, described are exemplary devices and methods directed toward an interconnect for garment-borne electronics to provide waterproof, highly-flexible, inexpensive, current-carrying conductors to a distribution of connected devices.

In accordance with the concepts described herein, described are exemplary devices and methods directed toward a textile conductive bus containing a plurality of conductors.

In accordance with the concepts described herein, described are exemplary devices and methods directed toward a textile conductive bus containing a plurality of conductors each capable of carrying up to about 1 Ampere (A) of current.

In accordance with the concepts described herein, described are exemplary devices and methods directed toward a textile conductive bus containing a plurality of conductors having a cross-sectional diameter of less than about 1.5 mm, including all dielectric layers.

In accordance with the concepts described herein, described are exemplary devices and methods directed toward a textile conductive bus containing a plurality of conductors that support attaching a plurality of electronic components of various function.

In accordance with the concepts described herein, described are exemplary devices and methods directed toward a textile conductive bus containing a plurality of conductors using a repeating pattern of tethering points, thereby supporting communication and power connectivity for an integrated system.

In accordance with the concepts described herein, described are exemplary devices and methods directed toward a textile conductive bus containing a plurality of conductors comprising a length of approximately hundreds of feet and fabricated from liquid crystal polymer (LCP).

In accordance with the concepts described herein, described are exemplary devices and methods directed toward a textile conductive bus containing a plurality of conductors, spooled onto a bobbin, and fed into stitching or weaving equipment for connection and use.

In accordance with the concepts described herein, an exemplary method of forming a textile includes forming an electrical bus comprising at least one of: at least one top electrically conductive pad; and at least one bottom electrically conductive pad; a plurality of rows of a plurality of electrically conductive traces; a dielectric material between the at least one top electrically conductive pad, the plurality of rows of the plurality of electrically conductive traces, and the bottom electrically conductive pad; and at least one electrically conductive via connecting at least one of the at least one top electrically conductive pad and the bottom electrically conductive pad to at least one of the plurality of electrically conductive traces in at least one of the plurality of rows of the plurality of electrically conductive traces; and threading or otherwise arranging a textile thread around the electrical bus. In embodiments, the electrical bus comprises a one or more top electrical pads and no bottom pads. In embodiments, the electrical bus comprises one or more bottom electrical pads and no top pads. In embodiments, the electrical bus comprises one or more top electrical pads and one or more bottom pads. In embodiments, the electrical bus comprises a plurality of top electrical pads and a plurality of bottom electrical pads.

### BRIEF DESCRIPTION OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principles of the concepts described herein. Like reference numerals designate corresponding parts throughout the different views. For purposes of clarity, not every component may be labeled in every drawing. Furthermore, embodiments are illustrated by way of example and not limitation in the figures, in which:

FIG. 1 is a cross-sectional view of an example “textile conductive bus” (also sometimes referred to herein as a “multi-wire thread”);

FIG. 2 is a cross-sectional view of an alternate example textile conductive bus;

FIG. 3 is a cross-sectional view of a second alternate example textile conductive bus;

FIG. 4 is a perspective view of an example textile conductive bus which may be the same as or similar to one of the textile buses shown in FIGS. 1-3;

FIG. 4A is an end view of the example textile conductive bus of FIG. 4 taken across lines 4A-4A;

FIG. 4B is a cross-sectional view taken across lines 4B-4B of FIG. 4;

FIG. 4C is an exploded view of a portion of the example textile conductive bus of FIG. 4;

FIG. 5 is a perspective view of an example textile conductive bus;

FIG. 5A is a side view of an example textile conductive bus having at least one node attached hereto;

FIG. 6 is a block diagram of an example system employing an example textile conductive bus;

FIG. 7 is a side cross-sectional view of an example threading scheme for an example textile conductive bus; and

FIG. 7A is a side cross-sectional view of a second example threading scheme for an example textile conductive bus.

### DETAILED DESCRIPTION

Aspects and embodiments disclosed herein are not limited in application to the details of construction and the arrangement of components set forth in the following description or illustrated in the drawings. Aspects and embodiments disclosed herein are capable of being practiced or of being carried out in various ways. Also, the phraseology and terminology used herein is for the purpose of description and should not be regarded as limiting.

Aspects and embodiments disclosed herein include providing a textile conductive bus (also sometimes referred to herein as a “multi-wire thread”) that may include, for example, one or more individual conductors (e.g., in some embodiments twelve or more conductors) each capable of conducting about 1 ampere (A) of current, with a multi-wire thread cross-sectional diameter of 1.5 mm or less, including all dielectric materials. The concepts described herein may further include techniques for attaching a multitude of electronic components of various functions using a pattern of “tethering points” (also sometimes referred to herein as “pads”).

The textile conductive bus structures described herein may be formed or otherwise provided using lamination equipment and techniques. Additive manufacturing equipment and techniques may also be used to form some or all of the textile conductive bus structures described herein. For example, the structures described herein may be provided via fused deposition modeling (FDM) additive manufacturing techniques and equipment. The textile conductive bus structures may be fabricated into a length of, for example, hundreds of feet, using a single panel of laminated liquid crystal polymer (LCP) layers, and then cut and spooled onto a bobbin to be fed into stitching or weaving equipment.

According to one aspect, fused deposition and/or laminated embodiments of a textile conductive bus provided in accordance with the concepts described herein may be used for electrical interface applications in the fields of electronics, bioengineering, medical equipment, civil engineering, space applications and any commercial and military applications.

According to another aspect, the textile conductive bus structures described herein may also be used as a tunable antenna element. Such structures may be tunable according to, or by virtue of length, physical positioning and arrangement of the multi-wire thread, and the addition of termination/drive elements connected to pads at either end for performing receive and transmit functions.

According to another aspect, the textile conductive bus structures described herein may be used to form a sensor which functions by monitoring resistance and impedance changes due to temperature, moisture present across exposed electrical pads of the textile conductive bus, and mechanical strain effects on the textile conductive bus.

As described herein, the textile conductive bus may be flexible and have a tensile strength that may survive high strain environments. A conformal coating material may be applied to the textile conductive bus to make it waterproof. Conventional mask removal processes may be used at any point along the multi-wire thread length to selectively expose top and/or bottom pads of the textile conductive bus to enable conventional soldering and sintering paste techniques to create robust and low resistance contact between the textile conductive bus and at least one electronic device. Conventional thermoforming techniques applicable to LCP materials may be used to form sharp bends and rounded shapes, and to provide strain relief in the textile conductive bus.

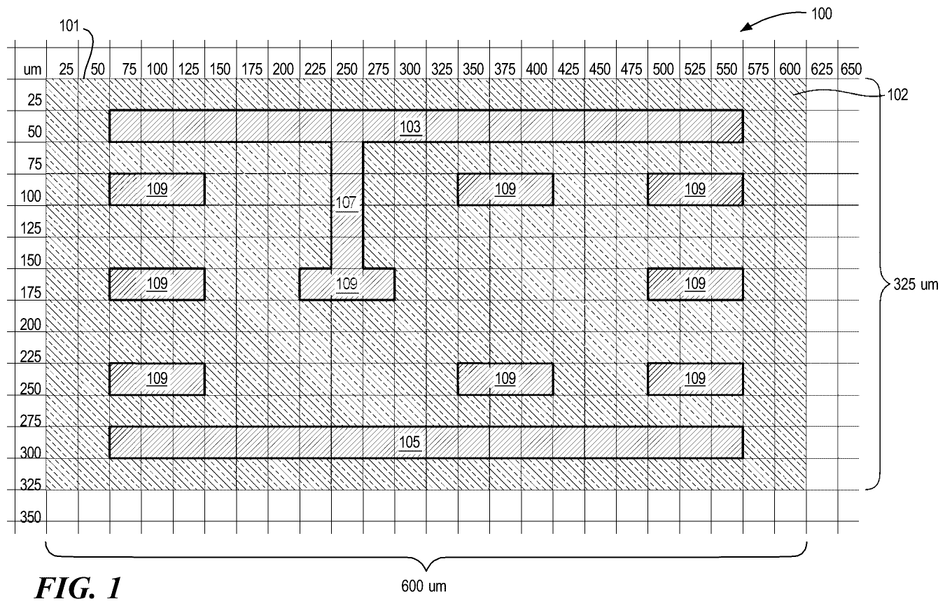

Referring now to FIG. 1, a textile conductive bus (also sometimes referred to herein as a “multi-wire thread” or more simply as “thread”) 100 may include a textile thread 101 and an electrical bus within the textile thread 101. The textile conductive bus 100 may include at least one top electrically conductive pad 103, at least one bottom electrically conductive pad 105, and one or more rows of a plurality of conductors 109, (e.g. traces) with three (3) rows being shown in the example of FIG. 1. While the example in FIG. 1 shows one top electrically conductive pad 103, three rows of conductors 109 and one electrically conductive bottom pad 105, one skilled in the art will recognize that the textile conductive bus 100 may include one or more of each component and is not limited to the specific number or configuration shown in the example embodiment.

A dielectric material 102 may be disposed between the textile thread 101, the top electrically conductive pad 103, the row(s) of the conductors 109, and the bottom electrically conductive pad 105. At least one electrically conductive via 107 may electrically couple the at least one top electrically conductive pad 103 to another electrical conductor (e.g., at least one of the conductors 109 or the bottom electrically conductive pad 105).

The top electrically conductive pad 103, the bottom electrically conductive pad 105, the plurality of rows of conductors 109, and electrically conductive via 107 may each comprise an electrically conductive material (e.g., a metal such as copper (Cu)). In embodiments, the top electrically conductive pad 103, the bottom electrically conductive pad 105, the plurality of rows of the conductors 109, and the electrically conductive via 107 may each conduct up to about 1 A of current.

In embodiments, the dielectric material 102 may comprise a liquid crystal polymer (LCP) which fuses to create a monolithic structure impermeable to fluids (i.e., waterproof) and provides a high tensile strength (e.g., a tensile strength on the order of or similar to that of steel). In embodiments, the dielectric material 102 may have a thickness of about 25 micrometers (μm) between the top electrically conductive pad 103 and an adjacent conductor 109. In embodiments, the dielectric material 102 may have a thickness of about 50 μm between two conductors 109.

In embodiments, the top electrically conductive pad 103 and the bottom electrically conductive pad 105 may each have a height of about 25 μm, a width of about 500 μm, and a length of about 500 μm. Each of the conductors 109 may have a height of about 25 μm, a width of about 75 μm, and a length up to about the width of the textile thread 101 (with the width of thread in the example embodiment shown in FIG. 1 being about 600 μm).

In embodiments, the electrically conductive via 107 may have a width of about 25 μm, and a length of about 75 μm. The electrically conductive via 107 may have a height sufficient to electrically connect one of the conductors 109 to at least one of the top electrically conductive pad 103 and the bottom electrically conductive pad 105.

According to one or more embodiments, the top electrically conductive pad 103 and the bottom electrically conductive pad 105 may comprise one of or a combination of two or more of: nickel (Ni) and gold (Au) to form electroless nickel immersion gold (ENIG) and Ni, palladium (Pd), and Au to form electroless nickel electroless palladium immersion gold (ENEPIG).

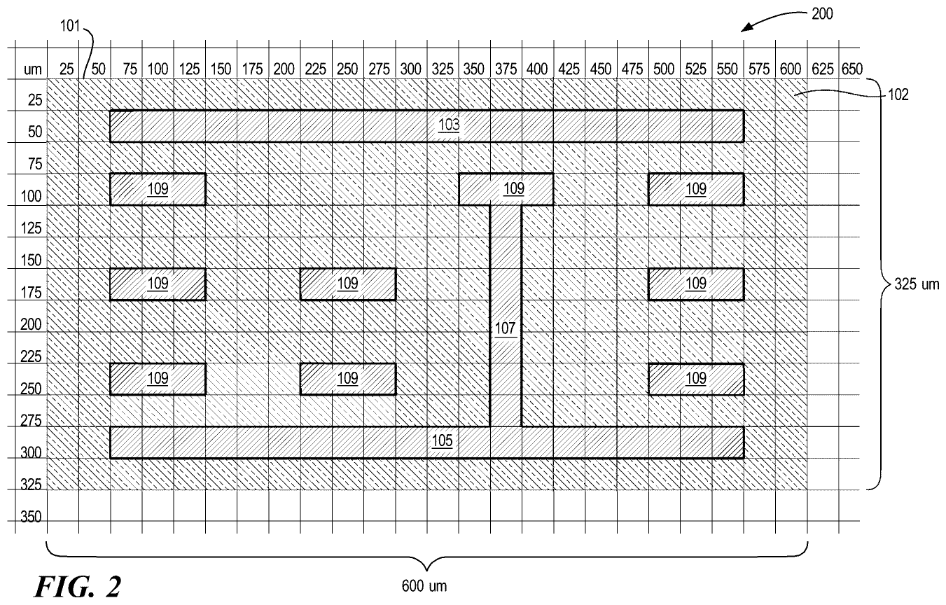

Referring now to FIG. 2, in which like elements of FIG. 1 are provided having like reference designations, a textile conductive bus 200 may include the same elements as the textile conductive bus 100 of FIG. 1 but in a different configuration. In the example embodiment of FIG. 2, the electrically conductive via 107 electrically may connect one or more of the conductors 109 to the bottom electrically conductive pad 105.

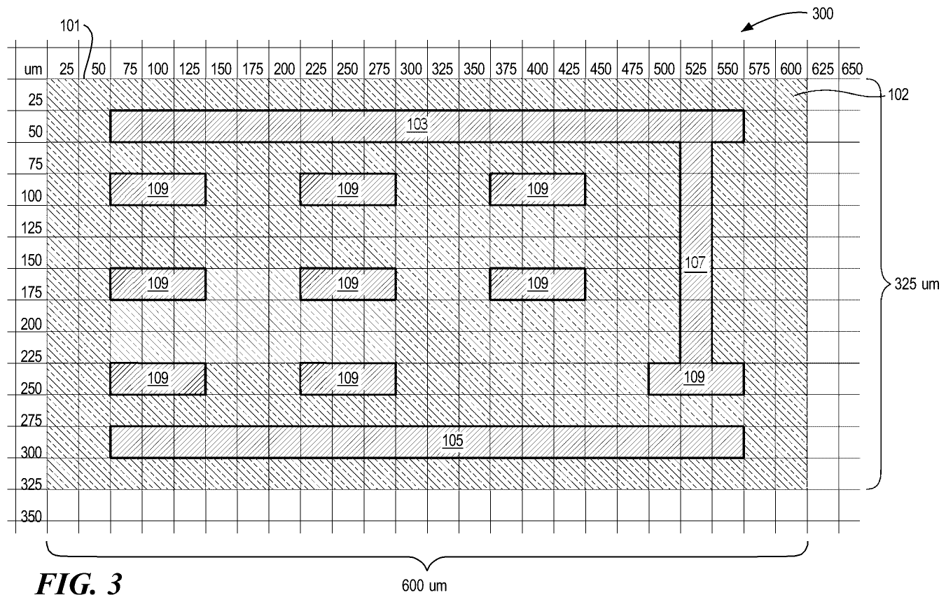

Referring now to FIG. 3, in which like elements of FIGS. 1 and 2 are provided having like reference designations, a textile conductive bus 300 may include the same elements as the textile conductive bus 100 of FIG. 1 but in a different configuration. In the example embodiment of FIG. 3, the electrically conductive via 107 electrically connects one or more conductors 109 to the top electrically conductive pad 103.

Thus, the embodiments of FIGS. 1-3 illustrate several different example configurations which may include the structures and techniques described herein. It should, therefore, be appreciated that the top electrically conductive 103 and the bottom electrically conductive pad 105 may be coupled to any electrically conductive traces 109 included in an electrically conductive textile thread (e.g., any thread shown in FIGS. 1-3) through one or more electrically conductive vias 107. That is, electrical signal paths may be formed in any combination of different vertical positions and/or different horizontal positions using conductive vias 107 as illustrated in FIGS. 1-3.

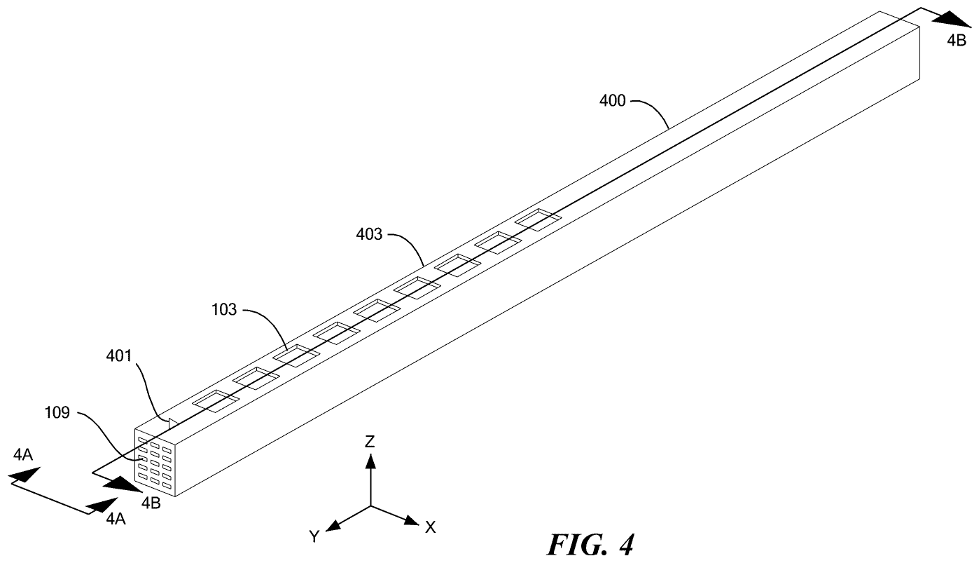

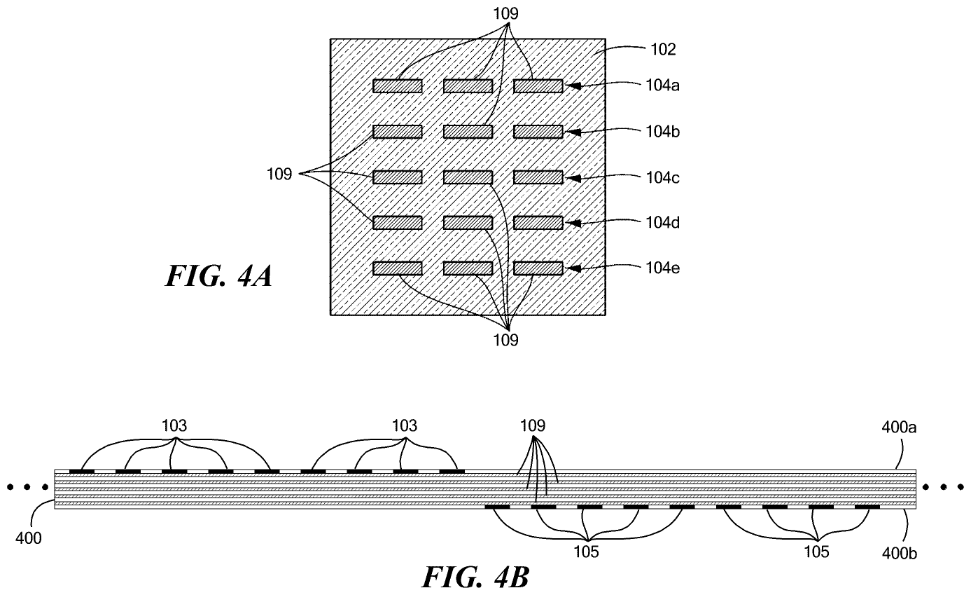

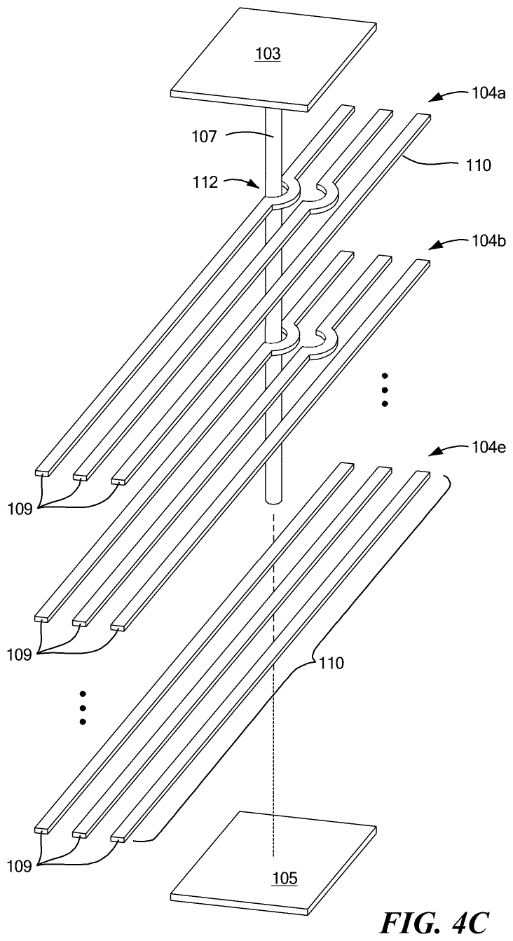

Referring now to FIGS. 4-4C, in which like elements are provided having like reference designations throughout the several views, a multi-wire thread 400 has first and second opposing surfaces 400a, 400b. One or more fiducials 401 may be disposed on one or both surfaces 400a, 400b (or even side surfaces) of multi-wire thread 400. Fiducials 401 may be helpful to identify orientation of thread 400 during assembly and integration of a thread in a system, such as a garment or the like. The fiducials 401 may indicate a location of one or more specific pads (e.g., a first pad in a group of pads). A first plurality of pads 103, here nine pads, may be exposed in the first (or top) surface of thread 400 (and thus pads 103 may be referred to as exposed top pads 103). A second plurality of pads 105 (FIG. 4B), here nine pads 105, may be exposed in the second (or bottom) surface of thread 400 (and thus pads 105 may be referred to as exposed bottom pads 105). It should be appreciated that the number of top pads may be the same as or different from the number of bottom pads. For example, the number of top pads 103 may be less than, greater than or equal to the number of bottom pads 105.

As may be most clearly seen in FIG. 4A, multi-wire thread 400 may include one or more rows of conductors 109. In the example embodiment of FIG. 4, the multi-wire thread 400 includes five (5) rows 104a-104e of conductors. Each row 104a-104e of conductors may comprise one or more conductors 109. In this example embodiment, each row of conductors comprises three (3) conductors 109. It should, however, be appreciated that the number of conductors 109 in each row may be the same or different than the number of conductors 109 in any other row. For example, the number of conductors 109 in row 104a may be less than, greater than or equal to the number of conductors 109 in any of rows 104b-104e; the number of conductors 109 in row 104b may be less than, greater than or equal to the number of conductors 109 in any of rows 104a, and 104c-104e; and so on and so forth.

Selecting additional conductors is possible through the following trade-offs: adding additional layers of one or more conductors to make the thread taller (e.g., increasing y dimension of the thread) and making the conductors a smaller cross sectional area (to hold x and y dimensions of the conductors the same, but reduce current capacity to less than about 1 A); or by making the conductive layers wider (increasing x dimension of conductors such as conductors 109) and holding the layer count fixed.

According to one or more aspects, the overall size of a multi-wire thread 400 (i.e., the width, height, shape and cross-sectional area of the thread) may be selected to suit the needs of a particular application. For example, in some applications it may be desired to mimic heavy thread, up to about 1.5 mm in diameter. However, machines exist that can stitch 3 mm thread and thus for some applications it may be desirable to provide the thread having a diameter of 3 mm. Such a thread may have nine (9) times the area of the area of a 1 mm thread, thereby allowing nine (9) times the conductor capacity (e.g., 81 conductors). In embodiments, using current LCP fabrication technology, a thread having up to three (3) layers of inner conductors and up to two (2) pad layers may be formed. In some embodiments, it may be desirable to provide a thread having a 3×3 arrangement of conductors (i.e., three rows and three columns of conductors) which may result in a thread having a substantially square cross-sectional shape.

As illustrated in FIGS. 1-3, the conductors 109 may be electrically coupled though via paths (e.g., vias 107 illustrated in FIGS. 1-3). Thus, any conductor 109 in multi-wire thread 400 may be electrically coupled to any other conductor 109 or to any one of the electrically conductive top and bottom pads 103, 105 via an appropriate configuration of via signal paths. By interconnecting desired electrically conductive top and bottom pads, 103, 105 and conductors 109, one or more buses on which one or more signals may propagate can be formed.

In the example embodiment shown in FIG. 4C, the dielectric has been removed to reveal electrically conductive signal paths 110 (also sometime referred to herein as “traces” 110) formed by conductors 109 and a conductive via 107. It should be noted that a first end of conductive via 107 is illustrated as being electrically coupled to a pad 103 and passes through (or extends through) several layers (or several ones of rows 104a-104e) of multi-wire thread 400. In this example, the second end of conductive via 107 is not shown as being connected to any structure but would typically be coupled to one or more conductors 109 in one or more rows 104a-104e or to pad 105. It should be appreciated that some traces 110 have a shift portion 112 (or “trace shift” 112) to avoid physically contacting via signal path 107.

In the example embodiment shown in FIG. 4C, two traces 110 in two different rows (e.g., rows 104a, 104b) are illustrated as having a trace shift 112. It should be appreciated that in some embodiments a single trace in a single row may comprise a plurality of trace shifts 112, or in some embodiments a plurality of traces in one or more rows may comprise one or more trace shifts 112. After reading the disclosure provided herein, one of ordinary skill in the art will appreciate how to select the number and placement of trace shifts required for use in a particular application.

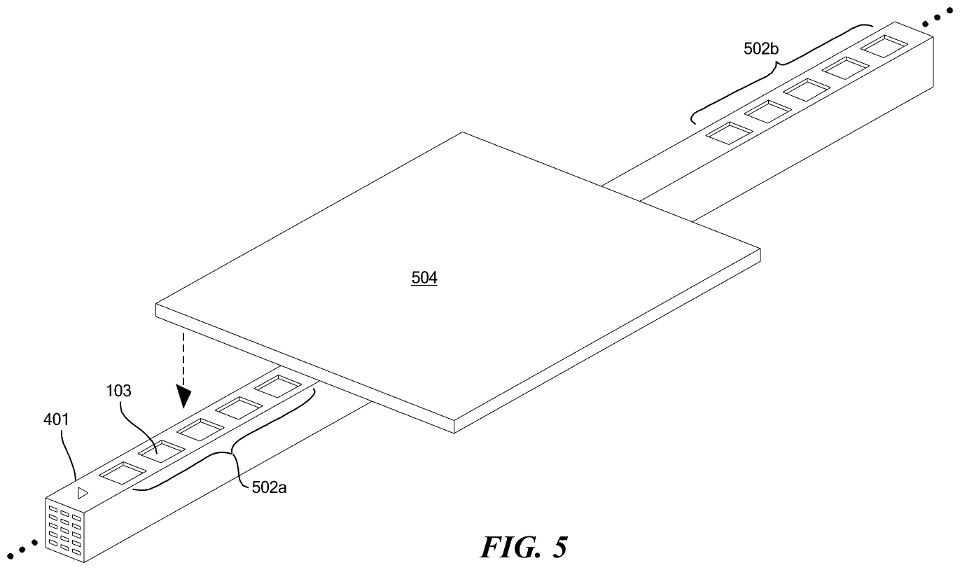

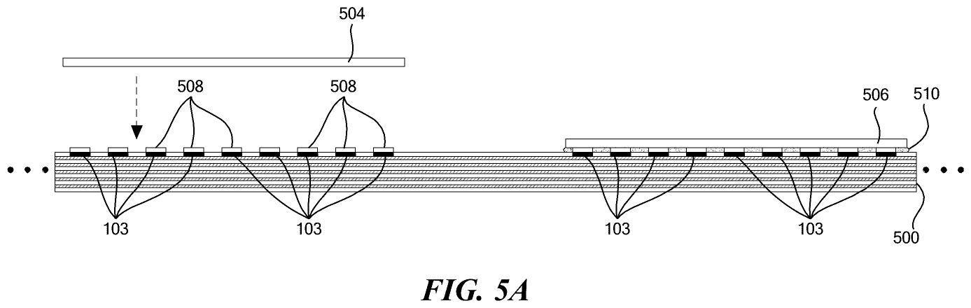

Referring now to FIGS. 5 and 5A, in which like elements are provided having like reference designations, a multi-wire thread 500 may include a plurality (here, first and second) groups of pads 502a, 502b. Each group of pads 502a, 502b may include one or more conductive pads 103 made accessible by mask removal for providing module connection points For example, each group of pads may comprise an array of exposed conductive pads. In embodiments, all pad groupings may be identical to permit flexibility in siting the module along the length. Pads on both sides of the thread allow for rotation of the thread during installation and therefore bottom or top connection points may be available to the module as the thread “upper surface” more than 50% of the time.

According to one aspect, when a thread is converted from a flat laminated flex circuit panel into laser-cut thread coiled on a spool, the thread may twist (e.g., during a spooling process). This cutting and/or spooling process may also result in a “rounded square”, or almost oval, cross section. The “upper surface” of an installed thread (e.g., a thread installed in a garment) may be the top or bottom “face” of the thread visible to one inspecting the thread (e.g., an inspector) when affixed to the fabric. However, this may change over a length of a thread when affixed in a system or structure depending upon where in the system (i.e., in which physical location) the thread is examined. That is, if a thread provided in accordance with the concepts described herein, is sewn, stitched or otherwise provided in a shirt or other garment, then pads exposed to (i.e., facing) an inspector at a cuff of the shirt may be top pads, but at the elbow they may be bottom pads, and so forth. Alternatively, all pads exposed to an inspector may be top pads, or all pads exposed to an inspector may be bottom pads. In this way, pads are accessible at regular intervals without thread manipulation/rotation which may be difficult (and in some applications, impossible) after installation of the thread.

In embodiments, all pad groupings may be substantially identical and certain pads could be exposed to attach a specific module, or all pads may be exposed for mechanical reasons. For example, pads for signals not needed by the module may still be present on the module as floating metal attachments for mechanical reinforcement, strain relief, or the like.

In the example embodiment of FIG. 5, pad group 502a includes nine (9) pads 103 (with only six (6) pads visible) and pad group 502b includes six (6) pads 103. A first module 504 such as an electrical circuit component or device, may be disposed over the first group of pads 502a. The number of pads to include in a pad group may depend, at least in part, upon one or more of a combination of: signal types and the number, size, type and spacing of connection points of the module to be coupled to the thread 500. In the example of FIG. 5, the module 504 may be, for example, 7 mm×7 mm and include nine (9) connection points. Therefore, all nine (9) pads 103 in the pad group 502a are able to couple to the module. In some module types, fewer pads may be needed and therefore the module size/area may be smaller. According to one aspect, the number of connection points in the module 504 may determine the number pads 103 to include in a pad group. After reading the disclosure provided herein, one of ordinary skill in the art will appreciate how to select the number, size and placement of pads in a pad group for use in a particular application.

It should be appreciated that in pad group 502a, the pads may be the same size and same shape. In pad group 502b, however, not all pads are the same size nor the same shape. Furthermore, in embodiments, the pads 103 in pad group 502b need not all be equally spaced from each other. For example, the edge-to-edge spacing of pads 103 and/or the center-to-center spacing of pads 103 need not be the same between each pad. The selection of the number, size, shape and spacing of pads 103 in a particular pad group may be made accounting for a variety of factors, including but not limited to, the number, size, shape and spacing of connectors on a module 504 to be coupled to the pad group.

In the example shown in FIGS. 5, 5A, modules 504 and 506 (FIG. 5A) are coupled to two textile conductive busses via pad groups 502a, 502b, respectively. In this example, module 504 may be electrically coupled to six (6) top electrically conductive pads 103 via pad group 502a. Thus, module 504 is electrically coupled to six (6) out of nine (9) conductive pads 103 via pad group 502a. In some embodiments, a module 504 may be disposed over and electrically coupled to all nine (9) conductive pads 103 in pad group 502a.

In one example embodiment, before attaching one or more modules (such as modules 504, 506) to a multi-wire thread (e.g., a multi-wire thread 500), it should be appreciated that one or more pads (such as top and/or bottom pads 103, 105) in the multi-wire thread 500 are first exposed so that contact points on the module may electrically connect with the pads of the multi-wire thread 500. The particular pads to expose may be selected as described above. Exposing pads may be accomplished via any technique including any mechanical, chemical or laser techniques to remove some, most or all dielectric which may cover the pad to which the module is intended to connect. Once the selected pads are exposed to allow an electrical connection to the contact points of the module, a conductive material (e.g., solder) may be applied or otherwise disposed over the exposed pads. Selected surfaces of the multi-wire thread 500 and the modules 504, 506 are aligned such that one or more electrical contacts on the modules are aligned over one or more electrical contacts (e.g., pads 103) on the thread. The modules 504, 506 may then be physically coupled to the thread 500. In embodiments, one or more electrical contacts on the modules 504, 506 may be electrically and physically coupled to one or more pads 103 on the thread 500. The modules 504, 506 may be physically coupled to the multi-wire thread 500 using any technique known to those of ordinary skill in the art including mechanical techniques (e.g., using mechanical fasteners) or via a suitable epoxy or glue or other adhesive.

FIG. 5A illustrates one module 504 aligned for attachment to multi-wire thread 500 and another module 506 physically coupled to the multi-wire thread 500. Solder or conductive ink 508 may be disposed, by printing or other mechanism, on the pad 103. Reference numeral 510 generally represents a mechanism for connecting the module 506 to the thread 500. Reference numeral 510 may represent one or more of three mechanisms for connecting the module 506 to the thread 500. One or more of each concept may be used in an embodiment. In embodiments, reference numeral 510 may represent an epoxy for waterproofing the solder joints, an anisotropic conductive film (ACF), or a solder preform. According to one aspect, the ACF may create a waterproof conductive path (e.g., after exposure to temperatures as low as 130° C.). In another aspect, the solder preform may not be waterproof, but may include patterned solder features that make an electrical connection during a reflow process).

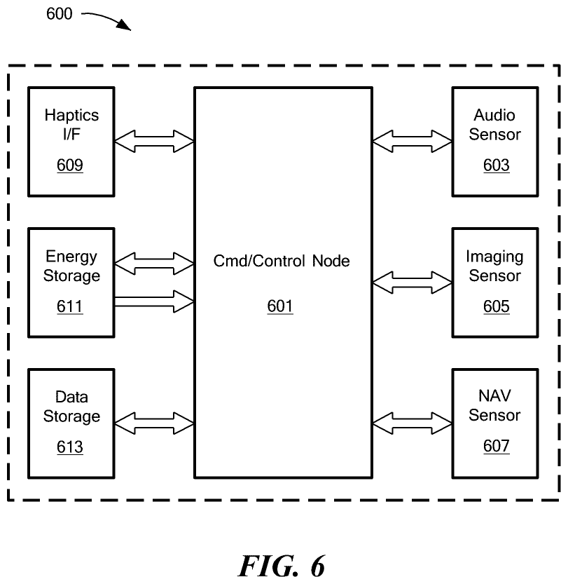

Referring now to FIG. 6, a block diagram of an example system 600 comprises one or more textile conductive buses (e.g., a multi-wire thread 500) having one or more components (or modules) coupled thereto. In embodiments, the components may correspond to one or more of: a command and control node (or module) 601; an audio sensor 603; an imaging sensor 605; a navigation (NAV) sensor 607; a haptics interface (I/F) 609; an energy storage device 611; and a data storage device 613. One or more textile conductive buses may be used to interconnect the components of the system 600. In embodiments, each of components 601, 603, 605, 607, 609, 611, 613 may be coupled to a single multi-wire thread by, for example, one or more pads as described above in conjunction with FIGS. 1-5A. In embodiments, one or more of components 601, 603, 605, 607, 609, 611, 613 may be coupled to a single multi-wire thread via one or more pads as described above in conjunction with FIGS. 1-5A. In embodiments, one or more of components 601, 603, 605, 607, 609, 611, 613 may be coupled to respective ones of a plurality of multi-wire threads.

According to one aspect, a textile conductive bus in accordance with the techniques described herein may be fabricated into a length of, for example, hundreds of feet, using a single sheet of liquid crystal polymer (LCP), and spooled onto a bobbin to be fed into stitching or weaving equipment. A multi-wire thread provided in accordance with the concepts described herein may be thread as a lock stitch or as piping, for example. It should be appreciated that multi-wire thread provided in accordance with the concepts described herein may find use in high-speed communications applications (e.g., high speed communications), power distribution applications and sensor applications.

Since the multi-wire thread itself may not include any electrical components, it may be stitched, woven or otherwise included as part of a fabric or textile. Electrical components may then be electrically coupled to the fabric or textile through one or more exposed pads in the multi-wire thread. In embodiments, a solder preform having a pattern which matches the pattern of an array of pads in the multi-wire thread may be used to facilitate electrical and/or mechanical connections between the multi-wire thread (and hence the fabric or textile of which the multi-wire thread is a part) and electrical components. Thus, the multi-wire threads provided in accordance with the techniques described herein may serve as an enabling structure for smart textiles.

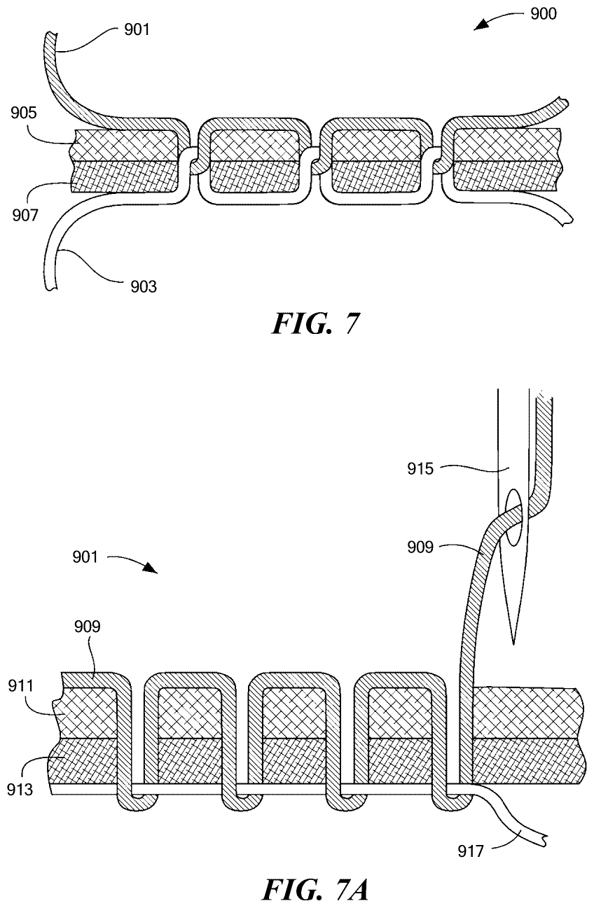

FIGS. 7 and 7A illustrate example threading schemes of an example multi-wire thread such as any of the multi-wire threads and textile conductive busses described above in conjunction with FIGS. 1-6. FIG. 7 is a side cross-sectional view of an example threading scheme 900 for an example textile conductive bus sewn using equal tension on both upper and lower threads in a lockstitch machine. In the example of FIG. 7, an upper thread 901 and a lower thread 903 may join together (or stitch together) two materials 905, 907 which may be separate pieces of material. Either one or both of the threads 901, 903 may be provided as a multi-wire threads such as any of the multi-wire threads described above in conjunction with FIGS. 1-6. Either, or both, of threads 901, 903 may comprise one or more multi-wire threads.

FIG. 7A is a side cross-sectional view of an alternative example threading scheme 901 for a textile conductive bus. The threading scheme may include a first thread (referred to herein as top thread 909) being used to join together (or stitch together) materials 911, 913, which may be separate pieces of material, and a second thread (referred to herein as a lower thread 917). The top thread 909 may be provided as a multi-wire thread. The top thread 909 may be fed through the eye of (or opening in) a sewing needle 915 and sewn into material 911, 913 (e.g., by a sewing machine) so as to join (or stitch) together materials 911, 913 and the lower thread 917.

Lower thread 917 may be provided as a multi-wire thread. In this example, the lower thread 917 may be delivered from a lower bobbin in a lockstitch sewing machine to reduce (and ideally minimize) small radius bends during thread feed. The lower thread 917 may be delivered under greater tension than the top thread 909, thereby preventing placement of the lower thread 917 close to the “center of material” (i.e., between materials 905, 907), instead allowing the lower thread 917 to lay flat and provide access to pad groupings in a low strain state.

FIG. 7A illustrates the two multi-wire threads, top thread 909 and lower thread 917, under mismatched tension. The lower thread 917 may be higher tension and the top thread 909 may be used like a conventional thread used to “lash down” the lower thread 917, at lower tension. It should be noted that the threading scheme 901 can be used to sew the multi-wire threads into one or more fabric layers, however for the purpose and ease of illustration, the example threading scheme 901 of FIG. 7A (and threading scheme 900 of FIG. 7) shown two layers. In the case of a single layer, for example, the top thread 909 may be used to lash down the lower thread 917.

Having described exemplary embodiments illustrating the concepts sought to be protected, it will now become apparent to one of ordinary skill in the art that other embodiments incorporating the concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable sub combination. Other embodiments not specifically described herein are also within the scope of the following claims.

Various embodiments of the concepts, systems, devices, structures and techniques sought to be protected are described herein with reference to the related drawings. Alternative embodiments can be devised without departing from the scope of the concepts, systems, devices, structures and techniques described herein.

It is noted that various connections and positional relationships (e.g., over, below, adjacent, etc.) are set forth between elements in the above description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming or other providing layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification.

As used herein, the terms “comprises,” “comprising, “includes,” “including,” “has,” “having,” “contains” or “containing,” or any other variation thereof, are intended to cover a non-exclusive inclusion (i.e., these terms are meant to encompass the items listed thereafter and equivalents thereof as well as additional items). For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” and “at least one” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection”.

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description herein, terms such as “upper,” “lower,” “right,” “left,” “vertical,” “horizontal, “top,” “bottom,” (to name but a few examples) and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements. Such terms are sometimes referred to as directional or positional terms.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways.

Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

What is claimed is:

1. A textile conductor, comprising:
a textile thread;
an electrical bus within the textile thread, wherein the electrical bus comprises:
at least one top electrically conductive pad;
at least one bottom electrically conductive pad;
a plurality of rows of a plurality of electrically conductive traces;
a dielectric material between the textile thread, the at least one top electrically conductive pad, the plurality of rows of the plurality of electrically conductive traces, and the at least one bottom electrically conductive pad; and
at least one electrically conductive via connecting the at least one top electrically conductive pad and the at least one bottom electrically conductive pad to at least one of the plurality of electrically conductive traces in at least one of the plurality of rows of the plurality of electrically conductive traces.

2. The textile conductor of claim 1, wherein the at least one top electrically conductive pad, the at least one bottom electrically conductive pad, the plurality of rows of the plurality of electrically conductive traces, and the at least one electrically conductive via comprise a metal.

3. The textile conductor of claim 2, wherein the metal is copper.

4. The textile conductor of claim 1, wherein the at least one top electrically conductive pad, the at least one bottom electrically conductive pad, the plurality of rows of the plurality of electrically conductive traces, and the at least one electrically conductive via each conduct up to 1 ampere of current.

5. The textile conductor of claim 1, wherein the dielectric material comprises a liquid crystal polymer.

6. The textile conductor of claim 1, wherein the at least one top electrically conductive pad and the at least one bottom electrically conductive pad each comprises a height of 25 micrometers (μm), a width of 500 μm, and a length of 500 μm.

7. The textile conductor of claim 1, wherein each of the plurality of electrically conductive traces comprises a height of 25 μm, a width of 75 μm, and a length up to a length of the textile thread.

8. The textile conductor of claim 1, wherein each of the at least one electrically conductive via comprises a height sufficient to connect one of the plurality of electrically conductive traces to one of the at least one top electrically conductive pad and the at least one bottom electrically conductive pad, a width of 25 μm, and a length of 75 μm.

9. The textile conductor of claim 1, wherein each of the at least one top electrically conductive pad and the at least one bottom electrically conductive pad comprises one of nickel (Ni) and gold (Au) to form ENIG and Ni, palladium (Pd), and Au to form ENEPIG.

10. The textile conductor of claim 1, wherein the dielectric material comprises a thickness of 25 μm between the at least one top electrically conductive pad and an adjacent one of the plurality of electrically conductive traces, a thickness of 50 μm between adjacent two of the plurality of electrically conductive traces.

11. A method of fabricating a textile conductor, comprising:
forming an electrical bus in a textile thread, wherein the electrical bus comprises:
at least one top electrically conductive pad;
at least one bottom electrically conductive pad;
a plurality of rows of a plurality of electrically conductive traces;
a dielectric material between the textile thread, the at least one top electrically conductive pad, the plurality of rows of the plurality of electrically conductive traces, and the at least one bottom electrically conductive pad; and
at least one electrically conductive via connecting the at least one top electrically conductive pad and the at least one bottom electrically conductive pad to at least one of the plurality of electrically conductive traces in at least one of the plurality of rows of the plurality of electrically conductive traces; and
forming a textile thread around the electrical bus.

12. The method of claim 11, wherein the at least one top electrically conductive pad, the at least one bottom electrically conductive pad, the plurality of rows of the plurality of electrically conductive traces, and the at least one electrically conductive via comprise a metal.

13. The method of claim 12, wherein the metal is copper.

14. The method of claim 11, wherein the at least one top electrically conductive pad, the at least one bottom electrically conductive pad, the plurality of rows of the plurality of electrically conductive traces, and the at least one electrically conductive via each conduct up to 1 ampere of current.

15. The method of claim 11, wherein the dielectric material comprises a liquid crystal polymer.

16. The method of claim 11, wherein the at least one top electrically conductive pad and the at least one bottom electrically conductive pad each comprises a height of 25 μm, a width of 500 μm, and a length of 500 μm.

17. The method of claim 11, wherein each of the plurality of electrically conductive traces comprises a height of 25 μm, a width of 75 μm, and a length up to a length of the textile thread.

18. The method of claim 11, wherein each of the at least one electrically conductive via comprises a height sufficient to connect one of the plurality of electrically conductive traces to one of the at least one top electrically conductive pad and the at least one bottom electrically conductive pad, a width of 25 μm, and a length of 75 μm.

19. The method of claim 11, wherein each of the at least one top electrically conductive pad and the at least one bottom electrically conductive pad comprises one of nickel (Ni) and gold (Au) to form ENIG and Ni, palladium (Pd), and Au to form ENEPIG.

20. The method of claim 11, wherein the dielectric material comprises a thickness of 25 μm between the at least one top electrically conductive pad and an adjacent one of the plurality of electrically conductive traces, a thickness of 50 μm between adjacent two of the plurality of electrically conductive traces.
